(19) United States
(12) Patent Application Publication
(10) Pub. No.: US 2026/0298789 A1
(43) Pub. Date: Oct. 1, 2026

(54) CORNER DROP TEST SYSTEM FOR POWER LITHIUM BATTERY CELL IN TRANSPORTATION ENVIRONMENT AND METHOD THEREOF

(71) Applicant: Chongqing Jiaotong University, Chongqing (CN)

(72) Inventors: Xingliang LIU, Chongqing (CN); Jinzhong WU, Chongqing (CN); Yihan PAN, Chongqing (CN); Yuanqiang LIU, Chongqing (CN); Zhiyuan BAI, Chongqing (CN)

(73) Assignee: Chongqing Jiaotong University, Chongqing (CN)

(21) Appl. No.: 19/329,016

(22) Filed: Sep. 15, 2025

(30) Foreign Application Priority Data
Mar. 26, 2025 (CN) 202510367102.5

(51) Int. Cl. G01N 3/303; G01N 3/06; G01N 23/046; G01N 23/06; G06T 7/00; H01M 10/42

(52) U.S. Cl. CPC G01N 3/303; G01N 3/068; G01N 23/046; G01N 23/06; G06T 7/0004; H01M 10/4285; G01N 2203/0062; G01N 2203/0222; G01N 2223/611; G06T 2207/10081

(57) ABSTRACT

A corner drop test system for a power lithium battery cell in a transportation environment includes a drop control module including a drop table configured to adjust the drop height and angle of the battery, a positioning fixture, and a parameter control module. The parameter control module sets the drop height according to different transportation types, such as road, rail, waterway, and air transportation, and classical drop scenarios. An environment simulation module uses a temperature control chamber to simulate high and low temperature environments during transportation, wherein the drop table and the positioning fixture are disposed in the temperature control chamber. A damage analysis module uses an industrial CT scanner to scan the battery after dropping to generate a three-dimensional reconstructed image, and quantify internal damage characteristics.

### CROSS-REFERENCE TO RELATED APPLICATIONS

This application claims priority to Chinese Patent Application No. 202510367102.5, filed on Mar. 26, 2025, which is incorporated herein by reference in its entirety.

### TECHNICAL FIELD

The present disclosure relates to the technical field of power battery testing, and specifically relates to a corner drop test system for a power lithium battery cell in a transportation environment and a method thereof.

### BACKGROUND

During the transportation of power lithium battery cells, the drop test constitutes a critical link in evaluating battery safety and structural integrity. However, the prior art exhibits significant deficiencies and limitations in practical application scenarios. Existing drop test, primarily targeted at the design of the overall packaging unit, requiring the packaging unit to undergo a free fall from different heights, but these standards fail to adequately consider extreme impact scenarios that individual cells may encounter during transportation.

Existing drop tests employ “no fire, no explosion” as the pass criterion. For example, “no rupture outside the explosion-proof valve” but does not address the risk of internal micro-short circuits. Internal damage caused by drop impacts may progressively worsen during use, ultimately leading to thermal runaway.

Significant differences exist between domestic and international drop test standards, resulting in inconsistent test methods and difficulties in targeted optimization design. IEC 62133-2 requires a 1.0 m random-orientation drop, while GB/T 36276-2023 requires energy storage cells to be dropped from 1.5 m, yet provides no clear specification for power battery cells.

### SUMMARY

The present disclosure aims to provide a corner drop test system for a power lithium battery cell in a transportation environment and a method thereof, to solve the technical problems in existing power battery drop tests wherein test designs deviate from the actual transportation environment and evaluation indices have blind spots, which result in low effectiveness of test results.

To achieve the above objective, the present disclosure adopts the following technical solution.

A corner drop test system for a power lithium battery cell in a transportation environment includes a parameter control module, a drop control module, an environment simulation module, and a damage analysis module.

The parameter control module is configured to set a drop height for a battery corner drop test according to a pre-established correspondence between a transportation type, a drop scenario, and the drop height.

The drop control module is configured to perform the battery corner drop test according to the set drop height and a drop angle; wherein the drop control module comprises a drop table and a positioning fixture; and the drop table is configured to adjust the drop height for the battery corner drop test, and the positioning fixture is configured to adjust the drop angle for the battery corner drop test.

The environment simulation module comprises a temperature control chamber, wherein the temperature control chamber is configured to simulate high and low temperature environments during transportation according to the transportation type; and the drop table and the positioning fixture are located in the temperature control chamber.

The damage analysis module is configured to scan a battery image after dropping, generate a three-dimensional reconstructed image of an internal structure of the battery based on the battery image, quantify internal damage characteristics of the battery through the three-dimensional reconstructed image, determine a battery damage level based on the internal damage characteristics of the battery, and determine a transportation risk under the corresponding transportation type and transportation packaging improvement suggestions based on the battery damage level.

The principles and advantages of this solution are as follows. In practical application, when a corner drop test of a power lithium battery cell in a transportation environment is required, the parameter control module is first utilized to set an appropriate drop height according to the transportation type of the battery, such as road transportation, rail transportation, and the like, and classical drop scenarios, thereby achieving a high degree of matching between the test scenario and the practical application. Simultaneously, by adjusting the temperature control chamber of the environment simulation module to high or low temperature conditions likely to occur in the corresponding transportation environment, and combining this with drop impact, a thermal-mechanical coupling effect is formed, which simulates the impact resistance of the battery in a state of low-temperature embrittlement or high-temperature expansion. The battery is mounted on the positioning fixture, and after adjusting the drop angle, the drop test is performed from the drop table according to the set height. After test completion, the industrial Computed Tomography (CT) scanner of the damage analysis module scans the battery after dropping to generate a three-dimensional reconstructed image, quantitatively analyzes internal damage characteristics of the battery, accurately identifies hidden damage such as micro-cracks, electrode misalignment, and the like, and finally determines the safety of the battery when facing the transportation type corresponding to the test height. This complete test process effectively improves the accuracy and reliability of the transportation safety assessment for power lithium battery cells.

The parameter control module sets the drop height for the battery corner drop test according to different transportation types and classical drop scenarios. Based on transportation accident investigation data, the set drop height better aligns with the drop situations that the battery may encounter during actual transportation, and fully considers extreme impact scenarios that the individual cell may face during transportation. The environment simulation module uses the temperature control chamber to simulate high and low temperature environments during transportation, allowing the drop test to be conducted under conditions closer to real transportation environments, thereby overcoming the deficiency of existing test standards which fail to consider the influence of transportation ambient temperature on battery dropping. The damage analysis module uses the industrial CT scanner to scan the battery after dropping to generate a three-dimensional reconstructed image and quantify the internal damage characteristics of the battery. Compared with existing tests that employ “no fire, no explosion” as the pass criterion and only focus on external rupture, this scheme uses internal damage characteristics as parameters for evaluation and determination, which reflects the safety condition of the battery after drop impact more directly and accurately, and solves the problems that existing standards do not address the risk of internal micro-short circuits and that internal damage caused by drop impact may gradually worsen during use and eventually lead to thermal runaway.

By uniformly adopting a test scheme based on the transportation type and transportation environment settings, the present disclosure avoids the problem of inconsistent test methods and difficulties in targeted optimization design caused by significant differences between domestic and international drop test standards, making the test results more comparable and targeted.

Preferably, as an improvement, the transportation type comprises road transportation, rail transportation, water transportation, and air transportation.

The drop scenarios for road transportation comprise manual handling drops and forklift and rack operation drops.

The drop scenarios for rail transportation comprise forklift and rack operation drops.

The drop scenarios for water transportation comprise container transfer drops.

The drop scenarios for air transportation comprise aircraft cargo hold drops.

The drop height range for manual handling drops is 0.8 m to 1.2 m, the drop height range for forklift and rack operation drops is 1.5 m to 3.5 m; the drop height for container transfer drops is 6 m; and the drop height for aircraft cargo hold drops is 5.4 m.

The beneficial effect of this improvement is that: setting the test height according to specific drop scenarios for each transportation type enables precise simulation of the impact level that the battery may experience in that transportation environment, facilitates identification of potential safety issues of the battery under different specific scenarios, and provides a more accurate basis for the safety design and transportation protection of the battery.

Preferably, as an improvement, the parameter control module is further configured to set the drop angle for the battery corner drop test.

The beneficial effect of this improvement is that: during actual transportation, the battery cell does not always collide with the ground or other objects on a flat surface; in many cases, the corner area first contacts the impact surface. The parameter control module, being configured to set the drop angle for the battery corner drop test, enables simulation of more drop angles that may actually occur, makes the test closer to the real transportation environment, and thus enables a more comprehensive evaluation of the safety performance of the battery under different drop angles.

Preferably, as an improvement, the internal damage characteristics of the battery comprise: a wrinkling area ratio of a battery electrode plate, a crack length of a battery separator, and a displacement of a battery tab.

The wrinkling area ratio of the battery electrode plate is calculated using an image segmentation algorithm by: segmenting a battery electrode plate region in the three-dimensional reconstructed image using the image segmentation algorithm to separate a contour of the battery electrode plate and determine an area of the battery electrode plate; identifying wrinkled portions on a surface of the battery electrode plate caused by drop impact; extracting all wrinkled regions on the battery electrode plate and calculating a total area of the wrinkled regions; and obtaining the wrinkling area ratio of the battery electrode plate by comparing the total area of the wrinkled regions with the area of the battery electrode plate.

The crack length of the battery separator is calculated using an edge detection algorithm by: identifying a separator region image in the three-dimensional reconstructed image; identifying edge portions where grayscale values undergo an abrupt change in the separator region image using the edge detection algorithm; capturing a starting point, an extension path, and an endpoint of a crack based on the edge portions; and calculating to obtain the crack length of the battery separator.

The displacement of the battery tab is calculated using a point cloud registration technique by: acquiring three-dimensional point cloud data of the battery tab after dropping; simultaneously retrieving original three-dimensional point cloud data of the battery tab before dropping; aligning and matching the two sets of point cloud data using the point cloud registration technique; finding a spatial position correspondence of each preset feature point on the battery tab before and after dropping; calculating a displacement vector of each preset feature point; and integrating to obtain the displacement of the battery tab; wherein if the displacement of the battery tab is greater than a preset tab displacement threshold, electrode plate fracture is determined.

The beneficial effect of this improvement is that: electrode plate wrinkling may affect internal electrochemical reactions and current transmission of the battery, and quantifying the wrinkling area ratio enables a more intuitive understanding of the damage condition of the electrode plate; the integrity of the separator is critical for battery safety, and the presence of cracks may lead to serious problems such as internal short circuits of the battery and other similar failures. Quantifying the crack length facilitates assessment of the extent of separator damage; the displacement of the tabs reflects the degree of deformation of the internal structure of the battery under impact, which is of great significance for evaluating the connection stability and electrical performance of the battery. By performing quantitative analysis of multiple internal damage characteristics, including the wrinkling area ratio of the electrode plates, the crack length of the separator, and the displacement of the tabs, the extent of battery damage after drop impact can be comprehensively evaluated.

Preferably, as an improvement, when the damage analysis module determines the battery damage level based on the internal damage characteristics of the battery and determines the transportation risk under the corresponding transportation type and the transportation packaging improvement suggestions based on the battery damage level.

If the wrinkling area ratio of the battery electrode plate is less than 5% and no separator crack is present, the battery is determined to have Level-One damage, and transportation is permitted.

If the crack length of the separator is greater than 2 mm, or the wrinkling area ratio of the battery electrode plate is between 5% and 15%, the battery is determined to have Level-Two damage, and a warning and reinforced packaging are required.

If electrolyte leakage or electrode plate fracture is identified, the battery is determined to have Level-Three damage, and transportation is prohibited.

If a level-three damage rate in a plurality of tests under a combination of a certain height and angle for a test battery is greater than or equal to 20%, the battery is considered not capable of safely completing the corresponding transportation type.

The beneficial effect of this improvement is that: the clear determination criteria provide a unified evaluation standard for different test personnel, reducing inconsistencies in evaluation results due to subjective judgment differences. This helps ensure fairness and objectivity in battery safety assessment, improving the credibility and comparability of evaluation results. Through determination of battery damage levels and corresponding handling measures, batteries with potential safety hazards can be identified and processed in a timely manner, reducing the risk of safety incidents during transportation, and ensuring the safety of personnel, property, and the environment.

When the wrinkling area ratio of the electrode plate is less than 5% and no separator crack is present, the damage is determined as Level-One damage and transportation is permitted. This indicates that the battery has sustained minor damage after drop impact, with minimal impact on transportation safety, allowing continued transportation and avoiding unnecessary transportation interruptions and cost increases. If the crack length of the separator is greater than 2 mm, or the wrinkling area ratio of the electrode plate is between 5% and 15%, the damage is determined as Level-Two damage, and a warning and reinforced packaging are required. This handling method alerts relevant personnel that the battery has certain damage risks, and reinforced packaging can reduce the possibility of further damage during transportation, ensuring transportation safety. When electrolyte leakage or electrode plate fracture occurs, the damage is determined as Level-Three damage and transportation is prohibited. These two conditions indicate that the battery has sustained severe damage with significant potential safety hazards, and thus continued transportation may lead to more serious consequences such as fire or explosion. Prohibiting transportation can effectively prevent the occurrence of safety incidents.

Preferably, as an improvement, the corner drop test system further comprises a drop data acquisition module, the drop data acquisition module comprising a high-speed camera configured to capture an instant when the battery contacts upon dropping, a three-axis accelerometer configured to collect acceleration changes of the battery at the moment of dropping, strain gauges configured to collect corner stress changes of the battery during dropping, and a laser range finder configured to detect a shell deformation rate of the battery after dropping.

The damage analysis module is further configured to generate a test report for a tester, the test report comprising CT image evidence, the battery damage level, and the transportation packaging improvement suggestions; wherein the transportation packaging improvement suggestions are obtained by analyzing data acquired by the drop data acquisition module.

The beneficial effect of this improvement is that: the collaborative operation of multiple high-precision devices enables more accurate acquisition of various physical quantity changes during the battery drop process, avoiding measurement errors and limitations that may exist with a single device. Through comprehensive analysis of these data, the actual stress conditions and damage mechanisms of the battery under drop impact can be understood more precisely, providing more reliable basis for subsequent damage assessment and packaging improvement.

Preferably, as an improvement, the drop table comprises a drop panel configured to impact and contact with the dropping battery, the drop panel is provided with a lifting mechanism configured to control a height of the positioning fixture, the positioning fixture comprises a connection base, a support plate assembly, and an electromagnetic chuck; the support plate assembly and an electromagnetic chuck assembly are mounted on the connection base, and the connection base is in transmission connection with the lifting mechanism.

The lifting mechanism is a screw lifting mechanism, a screw is vertically arranged, and a driving end of the screw is directly connected to a servo motor via a coupling, a nut is threadedly engaged with the screw of the lifting mechanism, and the connection base is fixedly connected to the nut, converting a rotational motion of the screw into a vertical movement of the connection base, thereby controlling the battery drop height.

The electromagnetic chuck assembly comprises a horizontal connecting rod, a vertical connecting rod, and an electromagnetic chuck, the vertical connecting rod includes a first vertical connecting rod and a second vertical connecting rod, both ends of the horizontal connecting rod are connected to the first vertical connecting rod and the second vertical connecting rod respectively through snap-fit components, a lower end of the first vertical connecting rod is fixedly connected to the connection base, and a lower end of the second vertical connecting rod is fixedly provided with the electromagnetic chuck.

The support plate assembly is configured to provide a placement plane for a battery to be tested, and comprises a first support plate and a second support plate arranged in parallel; the first support plate and the second support plate are arranged opposite to each other and are in transmission connection with a transmission mechanism; and the transmission mechanism drives the first support plate and the second support plate to move toward each other to close or move away from each other to open.

When the first support plate and the second support plate move toward each other to close, a circular hole is provided on a contact line between the first support plate and the second support plate, and the circular hole is configured to receive a corner to be dropped of the battery to be tested; the electromagnetic chuck is located above the circular hole and is configured to fix a non-adjacent diagonal corner of the dropping corner of the battery; a coil in the electromagnetic chuck is connected to a power supply; and operation or deactivation of the electromagnetic chuck is controlled by controlling connection or disconnection of the coil and the power supply.

The beneficial effect of this improvement is that: the first support plate and the second support plate in the support plate assembly can be moved toward each other to close or moved away from each other to open through the transmission mechanism. When the first support plate and the second support plate are moved toward each other to close, the circular hole at the contact line is configured to receive the corner to be dropped of the battery to be tested. This design enables the battery to be placed at the circular hole at any angle, provides convenience for accurately setting the battery drop angle, and meets diverse requirements for drop angles in different test scenarios. The electromagnetic chuck is located above the circular hole and is configured to fix a non-adjacent diagonal corner of the dropping corner of the battery. By controlling the connection or disconnection between the coil in the electromagnetic chuck and the power supply, fixation or release of the battery can be quickly achieved. After the battery is fixed, the battery can be ensured to maintain the set angle before dropping, improving the accuracy and stability of drop angle control. The method of using the electromagnetic chuck to fix the battery has simple and rapid operation, and can complete fixation and release of the battery in a short time. Compared with traditional fixation methods, this method greatly reduces test preparation time, improves test efficiency, and enables more drop tests to be conducted within the same time period, thereby obtaining more abundant test data.

The electromagnetic chuck can achieve instant disconnection, and quickly releases the fixing force on the battery at the moment of battery dropping, allowing the battery to drop in a manner close to a free state. This minimizes the intervention of external fixing devices in the battery drop process, ensures the authenticity and reliability of the drop test, and makes the test results better reflect the impact resistance performance of the battery in actual transportation. The electromagnetic chuck has adjustability and can adapt to batteries of different sizes. Regardless of the size of the battery, stable fixation of the dropping corner of the battery can be achieved by adjusting the position and suction force of the electromagnetic chuck. This universality enables the drop table to be suitable for testing multiple types and specifications of power lithium batteries, improving the application range and practicality of the test system.

Preferably, as an improvement, the high-speed cameras capture the battery dropping process from a plurality of angles including front, side, and top views, wherein the high-speed cameras located directly in front of the drop table are configured to capture the instant when the battery contacts upon dropping; the three-axis accelerometer is fixed at a center of gravity position of the battery; and a plurality of strain gauges are uniformly distributed and fixed near the dropping corner of the battery.

The beneficial effect of this improvement is that: arranging a plurality of high-speed cameras to capture the battery drop process from different angles enables acquisition of detailed information of the battery drop from multiple perspectives. The high-speed camera located directly in front of the drop table is specifically configured to capture the instant when the battery contacts upon dropping, which can clearly record specific situations of the contact between the battery and the drop panel, such as contact posture and contact point position, providing intuitive and crucial visual basis for subsequent analysis of the mechanical behavior and damage mechanism of the battery at the moment of dropping. Fixing the three-axis accelerometer at the center of gravity position of the battery enables accurate measurement of the acceleration changes experienced by the battery during the drop process. Since the center of gravity is the key position where force is applied to an object, measuring acceleration at this position can more accurately reflect the impact strength and direction borne by the battery. A plurality of strain gauges uniformly distributed and fixed near the dropping corner of the battery can monitor the stress changes near the dropping corner of the battery during the drop process in real time. The dropping corner is the part of the battery most susceptible to damage during dropping. Through accurate measurement of stress, the stress characteristics and stress concentration situation at this part of the battery can be understood.

The present disclosure also discloses a corner drop test method for a power lithium battery cell in a transportation environment, for implementing the corner drop test system for the power lithium battery cell in the transportation environment, and the corner drop test method includes the following steps: S1, S2, S3, and S4.

S1, fixing a battery to be tested on a positioning fixture at a preset angle, and adjusting a drop table according to a transportation type to position the battery to be tested at a preset height.

S2, adjusting a predicted ambient temperature by an environment simulation module according to the transportation type; releasing the battery cell from the preset height to freely drop onto a drop panel by a drop control module; repeating a dropping process for a set number of times; and collecting drop data by a drop data acquisition module.

S3, scanning the dropped battery using an industrial CT scanner, constructing a three-dimensional reconstruction model, and extracting damage characteristics.

S4, determining a damage level of the dropped battery based on the damage characteristics; providing transportation suggestions; and generating an improvement suggestion report incorporating the drop data.

The beneficial effect of this improvement is that: adjusting the predicted environmental temperature by the environment simulation module according to the transportation type enables simulation of actual temperature conditions of the battery in different transportation environments. Because temperature affects battery performance and safety, simulating real environmental temperatures makes test results closer to the actual situation of the battery during transportation, improving test accuracy and reliability. Conducting drop tests under different temperature conditions enables comprehensive evaluation of the impact resistance performance and safety of the battery in various transportation environments. This helps identify potential problems of the battery at different temperatures and provides scientific basis for the transportation and use of the battery under different climatic conditions.

In step S2, the analysis of the drop trajectory using data collected by the high-speed camera in the drop data acquisition module comprises a landing angle distribution analysis, a rebound height attenuation analysis, and a motion trajectory deviation analysis.

The landing angle distribution analysis is performed to count a contact frequency for different corners and identify a high-risk drop posture, wherein reinforced protection is implemented for a corner having an acute angle landing probability exceeding 30%.

The rebound height attenuation analysis is performed to calculate a height difference of the battery before and after dropping and evaluate an energy absorption efficiency of a packaging material, wherein the packaging material is ideal if a rebound height is maintained within 10% of an original height.

The motion trajectory deviation analysis is performed to analyze an offset trajectory of a center of gravity of the battery during dropping and optimize an internal fixing device, wherein optimization comprises adding an anti-slip pad or a snap-fit structure.

The analysis of impact characteristics using data collected by the three-axis accelerometer comprises a peak acceleration threshold analysis, an impact pulse width analysis, and a spectral energy distribution analysis.

The peak acceleration threshold analysis is performed to establish an acceleration limit that the battery can withstand, wherein an impact level of ≥50 g is determined to cause internal structural failure, and packaging cushioning design requirements are derived accordingly.

The impact pulse width analysis is performed to analyze a duration of acceleration waveforms and select a cushioning material with a corresponding response speed, wherein a foam material is suitable for a long pulse and a honeycomb structure is suitable for a short pulse.

The spectral energy distribution analysis is performed to identify main frequency bands through a Fast Fourier Transform (FFT) and design a band-pass damping structure, wherein resonance peaks are suppressed using a viscoelastic material.

The analysis of structural strength using data collected by strain gauges comprises a stress concentration factor analysis, a stress wave propagation path analysis, and a cumulative fatigue damage analysis.

The stress concentration factor analysis is performed by generating a stress nephogram of a battery shell and performing topological optimization for an area where a safety factor is less than 1.5 and stress exceeds a material yield strength.

The stress wave propagation path analysis is performed by tracking a stress wave transmission trajectory and adding a stress-relief groove at a key node, the key node comprising a weld seam or a flange edge.

The cumulative fatigue damage analysis is performed to evaluate a repeated drop life using Miner's rule and optimize a standard for a number of packaging cycles.

The analysis of a deformation mode using data collected by the laser range finder comprises a permanent deformation amount control analysis, a dynamic stiffness matching analysis, and a modal shape optimization analysis.

The permanent deformation amount control analysis is performed by setting a shell deformation threshold, wherein a maximum allowable deformation rate for length, width, and height is 0.5%, and wherein a reinforcement rib is implemented or a high-strength steel is adopted if the threshold is exceeded.

The dynamic stiffness matching analysis is performed by analyzing a nonlinear stiffness variation of the shell during dropping and designing a variable stiffness buffer layer comprising a gradient foam structure.

The modal shape optimization analysis is performed by comparing a design mode with a measured vibration mode and adjusting a position of a packaging support point to avoid a resonance amplification effect. The industrial CT scanner is employed to scan the battery after dropping, construct a three-dimensional reconstruction model, and extract damage characteristics. Combined with data collected by the drop data acquisition module, comprehensive analysis of the battery's damage condition is performed from multiple dimensions. This comprehensive analytical method enables more accurate evaluation of both the extent and type of battery damage, thereby providing a more scientific basis for determining the damage level.

### BRIEF DESCRIPTION OF THE DRAWINGS

FIG. 1 is a structural diagram of a corner drop test system for a power lithium battery cell in a transportation environment of the present disclosure.

FIG. 2 is a flowchart of an embodiment of the present disclosure.

FIG. 3 is a structural diagram of a drop control module according to an embodiment of the present disclosure.

FIG. 4 is a scanned cross-sectional view of an inner portion of a battery according to an embodiment of the present disclosure.

FIG. 5 is a structural diagram of an electromagnetic chuck of the present disclosure.

FIG. 6 is a corner drop test method for a power lithium battery cell in a transportation environment of the present disclosure.

### DETAILED DESCRIPTION OF THE EMBODIMENTS

The present disclosure is further described in detail below through specific embodiments.

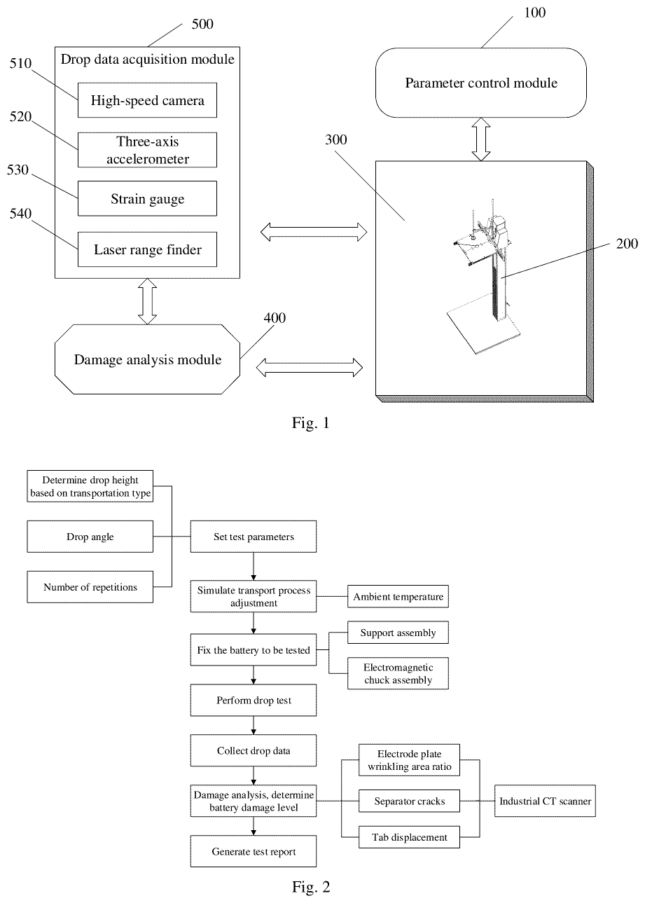

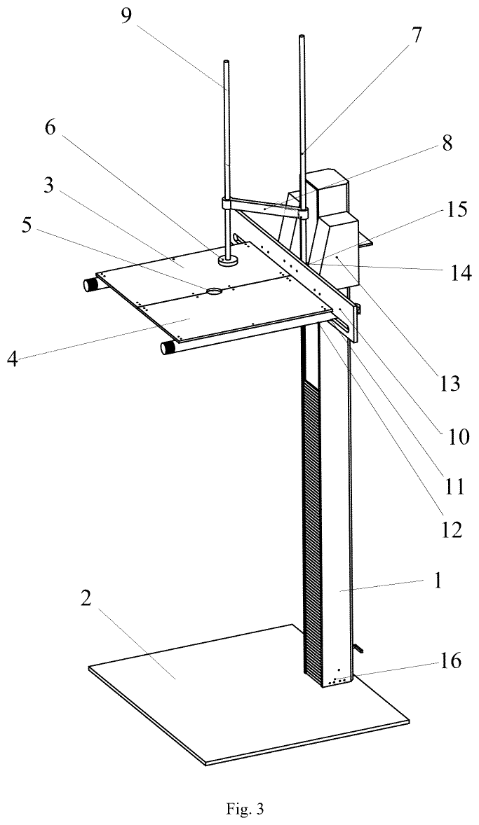

Basically as shown in FIG. 1 and FIG. 2, a corner drop test system for a power lithium battery cell in a transportation environment and a method thereof include the corner drop test system for the power lithium battery cell in the transportation environment and a method for implementing the system.

A corner drop test system for a power lithium battery cell in a transportation environment includes a drop control module 200 configured to perform the battery corner drop test according to the set drop height and a drop angle. The drop control module comprises a drop table and a positioning fixture; and the drop table is configured to adjust the drop height for the battery corner drop test, and the positioning fixture is configured to adjust the drop angle for the battery corner drop test.

As shown in FIG. 3, the drop table comprises a drop panel 2 configured to impact and contact with the dropping battery. The drop panel 2 is an ISTA-standard steel plate. The drop panel 2 is provided with a lifting mechanism 1 configured to control a drop height of the battery. The lifting mechanism 1 is a screw lifting mechanism. A screw is vertically arranged, and a driving end 14 of the screw is directly connected to a servo motor 16 via a coupling 15.

The positioning fixture comprises a connection base, a support plate assembly, and an electromagnetic chuck assembly. The support plate assembly and the electromagnetic chuck assembly are mounted on the connection base. A nut is threadedly engaged with the screw of the lifting mechanism 1, and the connection base is fixedly connected to the nut, converting a rotational motion of the screw into a vertical movement of the connection base.

The support plate assembly is configured to provide a placement plane for a battery to be tested and comprises a first support plate 3 and a second support plate 4 arranged in parallel. The first support plate 3 and the second support plate 4 are arranged opposite to each other and are in transmission connection with a transmission mechanism 12. The transmission mechanism employs a gear-rack transmission structure. A gear 10 is mounted on a motor output shaft 13. A rack 11 is fixedly connected to the first support plate 3 and the second support plate 4, respectively. The servo motor 16 drives the gear 10 to rotate, thereby driving the rack and the support plates to move toward each other to close or move away from each other to open. When the first support plate 3 and the second support plate 4 move toward each other to close, the battery to be tested is placed on the first support plate 3 and the second support plate 4. When the first support plate 3 and the second support plate 4 move away from each other to open, the battery to be tested falls freely from between the first support plate 3 and the second support plate 4.

When the first support plate 3 and the second support plate 4 are moved toward each other to close, a circular hole 5 is provided on a contact line between the first support plate 3 and the second support plate 4. The circular hole 5 in the closed state has a diameter of 80 mm. The circular hole 5 is configured to position a corner to be dropped of a battery to be tested, enabling the corner to be dropped to impact the drop panel at a preset angle precisely during dropping. An electromagnetic chuck assembly is disposed above the circular hole 5. Herein, the corner to be dropped refers to a predetermined corner portion of the power lithium battery cell that is about to impact and contact the drop panel (or simulated ground) during the corner drop test. The electromagnetic chuck assembly comprises a horizontal connecting rod 8, a vertical connecting rod, and an electromagnetic chuck 6. The vertical connecting rod includes a first vertical connecting rod 7 and a second vertical connecting rod 9. Both ends of the horizontal connecting rod 8 are connected to the first vertical connecting rod 7 and the second vertical connecting rod 9 respectively through snap-fit components. A lower end of the first vertical connecting rod 7 is fixedly connected to the connection base. A lower end of the second vertical connecting rod 9 is fixedly provided with the electromagnetic chuck 6. A spatial position of the electromagnetic chuck 6 is adjusted by adjusting snap-fit engagement positions of the horizontal connecting rod 8 with the first vertical connecting rod 7 and the second vertical connecting rod 9.

As shown in FIG. 5, the electromagnetic chuck 6 is configured to fix a non-adjacent diagonal corner of the dropping corner of the battery. The electromagnetic chuck 6 has a diameter of 100 mm. The electromagnetic chuck 6 employs a common electromagnetic chuck structure, comprising a housing 61, an iron core 62, a coil 64, a magnetic disk 65, and a magnetic isolation ring 63. The coil 64 is arranged within the housing 61. An end of the coil 64 is connected to the housing 61, and an outer end of the coil 64 is connected to a power supply via a lead wire. The iron core 62 is inserted into a central portion of the housing 61, with a gap provided between the iron core 62 and the housing 61. The iron core 62 is circular. The magnetic disk 65 is uniformly arranged on a front end surface of the iron core via the magnetic isolation ring 63. A cover is provided at a front end of the housing. This structure allows control of operation or stopping of the electromagnetic chuck 6 by controlling connection or disconnection between the coil and the power supply. An adsorption force magnitude is adjusted by regulating voltage to adapt to adsorption of batteries of different specifications. Meanwhile, a multi-group magnetic isolation ring structure design enables the iron core and the magnetic disk to form a uniform magnetic path, which is beneficial for enhancing stability of adsorbing the battery.

A parameter control module 100 is configured to set a drop height for a battery corner drop test according to a pre-established correspondence between a transportation type, a drop scenario, and the drop height. The transportation type comprises road transportation, rail transportation, water transportation, and air transportation.

The drop scenarios for road transportation comprise manual handling drops and forklift and rack operation drops.

The drop scenarios for rail transportation comprise forklift and rack operation drops.

The drop scenarios for water transportation comprise container transfer drops.

The drop scenarios for air transportation comprise aircraft cargo hold drops.

Since the drop height for manual handling is concentrated in the range of 0.8 m to 1.2 m, this embodiment selects 1 m as the corner drop test height for the manual handling drop scenario. For forklift and rack operation drops with a height range of 1.5 m to 3.5 m, this embodiment sets three height levels of 1.8 m, 2.3 m, and 3 m as the corner drop test heights for this scenario. For waterway transportation, drop accidents mostly occur during container transfer processes from the deck to the ground; therefore, the deck height of 6 m is selected as the corner drop test height for this scenario. For aircraft cargo hold drops, the cargo hold height is selected as the test height. Based on commonly used aircraft models, the cargo hold height of a Boeing 737 is 4.8 m, and that of an Airbus A320 is 6.0 m; thus, an intermediate value of 5.4 m is selected as the corner drop test height for the aircraft cargo hold scenario.

The parameter control module 100 is further configured to set an angle of the drop angle and a number of drops. The drop angle refers to the contact angle between the corner of the dropping battery and the drop plane during the corner drop test. In this embodiment, the drop angle is set to 45°, increasing stress concentration at the corners compared to traditional flat drops. This embodiment sets the number of drops to 5, meaning the drop test is repeated 5 times for each combination of height and angle.

The environment simulation module comprises a temperature control chamber 300 for simulating high and low temperature environments during transportation. Both the drop table and the positioning fixture are disposed within an internal space of the temperature control chamber. Through the temperature adjustment function of the temperature control chamber 300, the ambient temperature of the battery can be controlled during the battery drop test. This ambient temperature is set according to the temperature associated with the transportation type corresponding to the test height. Thereby, complex environmental conditions that the battery may encounter during actual transportation are more realistically simulated, ensuring that test results more closely reflect practical application scenarios.

The drop data acquisition module 500 comprises a high-speed camera 510 configured to capture an instant when the battery contacts upon dropping, a three-axis accelerometer 520 configured to collect acceleration changes of the battery at the moment of dropping, strain gauges 530 configured to collect corner stress changes of the battery during dropping, and a laser range finder 540 configured to detect a shell deformation rate of the battery after dropping.

A plurality of high-speed cameras 510 are arranged to capture the battery drop process from multiple angles. The high-speed camera 510 located directly in front of the drop table is configured to capture the instant when the battery contacts upon dropping. The three-axis accelerometer 520 is fixed at the center of gravity position of the battery to ensure accurate measurement of acceleration changes. The X/Y/Z axes of the three-axis accelerometer 520 are aligned with the principal inertial axes of the battery to prevent the mass of the three-axis accelerometer 520 itself from affecting the battery drop motion. A plurality of strain gauges 530 are uniformly distributed and fixed near the dropping corner of the battery to measure stress changes at the corner during dropping.

The high-speed camera 510 acquires video of the dropping instant for analyzing the battery drop trajectory, including parameters such as landing angle, rebound height, and other relevant parameters. The three-axis accelerometer 520 collects three-axis acceleration time-history curves of the battery at the moment of dropping for analyzing peak acceleration, impact pulse width, and other impact characteristics. The strain gauges 530 obtain dynamic strain time-history data of the battery for analyzing stress concentration factors at the battery corner, stress wave propagation paths, and other structural parameters. The laser range finder 540 detects the shell shape of the battery before and after dropping respectively, calculates a shell deformation displacement field, and utilizes this data for analyzing permanent deformation amount, dynamic stiffness, and other deformation characteristics of the battery shell.

Specifically, the high-speed cameras 510 capture the entire battery drop process from multiple angles. The analysis results (landing angle distribution, rebound height attenuation, motion trajectory deviation) serve the core function of reconstructing dynamic drop behavior, identifying high-risk scenarios, and optimizing protection strategies.

Landing angle distribution: counting the contact frequency of different corners (e.g., probability of acute angle landing >30%) enables precise identification of the postures in which the battery is most susceptible to damage during transportation drops. Based on this, packaging protection for high-risk corners can be specifically reinforced (e.g., by adding cushioning pads or designing directional limiting structures) to reduce the probability of damage during drops at these angles.

Rebound height attenuation: calculating the height difference of the battery before and after dropping (where the ideal rebound height is ≤10% of the original height) directly evaluates the energy absorption efficiency of the packaging materials. Excessive rebound indicates insufficient cushioning performance of the materials, guiding the replacement or upgrade of packaging materials (e.g., switching to high-elasticity foam or honeycomb structures) to reduce secondary drop impact.

Motion trajectory deviation: analyzing the offset trajectory of the battery's center of gravity reveals patterns of shaking or displacement caused by unstable fixation during transportation. This information optimizes internal fixing devices within the packaging (e.g., adding anti-slip pads or designing snap-fit structures) to prevent unintended drop postures resulting from positional shifts of the battery during transportation vibration.

The acceleration time-history curves collected by the three-axis accelerometer 520 are analyzed to obtain peak acceleration, impact pulse width, and spectral energy distribution. These parameters serve the core function of quantifying impact intensity and matching cushioning design with the battery's impact resistance limits:

Peak acceleration threshold: identifying the acceleration limit (e.g., internal structural failure of the battery occurs at ≥50 g) allows reverse derivation of the design requirements for the packaging cushioning layer. For instance, if tests show a peak acceleration of 60 g in a specific transportation scenario, a cushioning structure capable of attenuating the impact below 50 g must be designed (e.g., increasing cushion thickness or using gradient density materials) to ensure the core structure of the battery remains undamaged.

Impact pulse width: analyzing the duration of acceleration waveforms (long pulse/short pulse) enables precise matching of cushioning material types. For example, long-pulse impacts (e.g., road vibration drops) are suitable for foam materials (slow response but continuous energy absorption); short-pulse impacts (e.g., abrupt stops in aircraft cargo holds) require honeycomb structures (fast response, instant absorption of high-intensity impacts), avoiding protection failure due to material “mismatch”.

Spectral energy distribution: identifying the main frequency bands of impact energy through FFT transformation guides the design of band-pass damping structures. For example, if the main frequency band is concentrated at 100-200 Hz, viscoelastic materials (with high damping coefficients in this band) can be selected to suppress resonance peaks, preventing cumulative damage to the internal battery structure caused by resonance.

The dynamic strain data collected by the strain gauges 530 are analyzed to obtain stress concentration factor, stress wave propagation path, and cumulative fatigue damage. These parameters serve the core function of locating weak points in the battery shell and optimizing structural strength and fatigue resistance:

Stress concentration factor: Drawing a stress cloud diagram of the shell visually identifies areas where stress exceeds the material yield strength (e.g., locations with a safety factor <1.5). These areas are high-risk points for shell cracking. Based on this, topological optimization can be performed (e.g., adding fillets or increasing wall thickness) to enhance the impact resistance of the shell.

Stress wave propagation path: Tracking the transmission trajectory of stress waves within the battery reveals key nodes of stress concentration (e.g., weld seams, flange edges). Adding stress relief grooves at these nodes disperses stress transmission, avoiding local fractures caused by stress concentration (e.g., fractures at the connection between tabs and the shell).

Cumulative fatigue damage: Evaluating the impact of repeated drops on battery life using Miner's rule quantifies the limit of cyclic use for the packaging. For example, if analysis shows that fatigue damage reaches a critical value after 3 repeated drops for a specific packaging, its cyclic use standard can be set to ≤2 times, avoiding protection failure due to excessive use.

The permanent deformation amount, dynamic stiffness, and modal shape obtained by the laser range finder 540 through detecting shell deformation serve the core function of defining critical values for battery structural deformation and guiding the collaborative protection design of packaging and shell:

Permanent deformation amount: Setting a shell deformation threshold (e.g., deformation rate in length, width, and height <0.5%). Exceeding this threshold indicates insufficient deformation resistance of the shell. This guides the reinforcement of the battery shell structure (e.g., adding reinforcement ribs or switching to high-strength steel) or adding rigid support within the packaging to limit excessive shell deformation.

Dynamic stiffness: Analyzing the nonlinear change of shell stiffness during dropping enables the matched design of a variable stiffness buffer layer (e.g., gradient foam structure). For instance, using low-stiffness materials to absorb impact during the stiffness mutation stage and switching to high-stiffness materials to limit deformation during the stable stage achieves a cushioning effect that combines rigidity and flexibility.

Modal shape: Comparing design modes with measured vibration modes reveals matching issues between packaging support points and battery resonance frequencies. Adjusting the positions of support points (e.g., avoiding nodes corresponding to resonance frequency bands) prevents amplified shell deformation due to resonance during transportation vibration, reducing the risk of secondary damage to internal electrode plates and separators.

In summary, the data analysis from the four types of equipment forms a complete evaluation chain of “dynamic behavior-impact intensity-structural stress-deformation characteristics”, providing full-process support from “problem identification” to “solution formulation” for power lithium battery transportation safety testing, significantly enhancing the guiding value of test results for actual transportation scenarios.

The damage analysis module 400 uses an industrial CT scanner to scan the battery after dropping to generate a three-dimensional reconstructed image and quantify internal damage characteristics of the battery such as electrode plate wrinkling and separator micro-cracks.

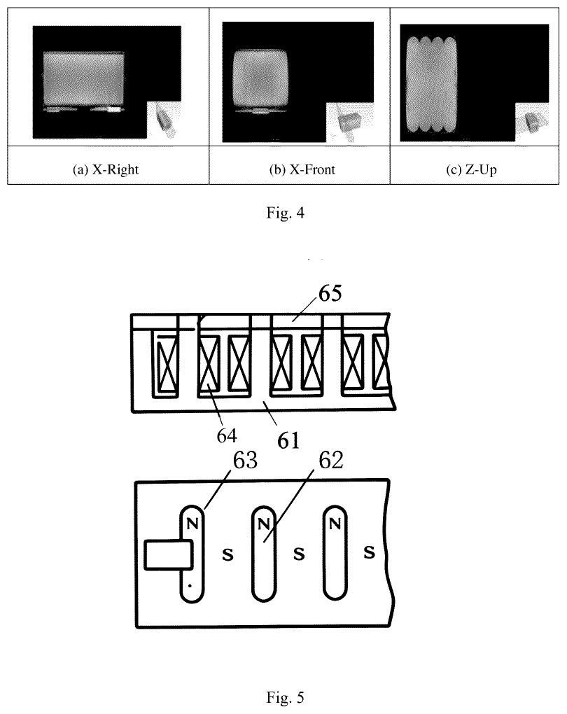

As shown in FIG. 4, the right sectional view, the front sectional view, and the top sectional view of the battery are respectively illustrated.

The internal damage characteristics of the battery comprise: a wrinkling area ratio of a battery electrode plate, a crack length of a battery separator, and a displacement of a battery tab.

Wherein the wrinkling area ratio of the battery electrode plate is calculated using an image segmentation algorithm by: segmenting a battery electrode plate region in the three-dimensional reconstructed image using the image segmentation algorithm to separate a contour of the battery electrode plate and determine an area of the battery electrode plate; identifying wrinkled portions on a surface of the battery electrode plate caused by drop impact; extracting all wrinkled regions on the battery electrode plate and calculating a total area of the wrinkled regions; and obtaining the wrinkling area ratio of the battery electrode plate by comparing the total area of the wrinkled regions with the area of the battery electrode plate.

The crack length of the battery separator is calculated using an edge detection algorithm by: identifying a separator region image in the three-dimensional reconstructed image; identifying edge portions where grayscale values undergo an abrupt change in the separator region image using the edge detection algorithm; capturing a starting point, an extension path, and an endpoint of a crack based on the edge portions; and calculating to obtain the crack length of the battery separator.

The displacement of the battery tab is calculated using a point cloud registration technique by: acquiring three-dimensional point cloud data of the battery tab after dropping; simultaneously retrieving original three-dimensional point cloud data of the battery tab before dropping; aligning and matching the two sets of point cloud data using the point cloud registration technique; finding a spatial position correspondence of each preset feature point on the battery tab before and after dropping; calculating a displacement vector of each preset feature point; and integrating to obtain the displacement of the battery tab; wherein if the displacement of the battery tab is greater than a preset tab displacement threshold, electrode plate fracture is determined.

A calculation-based damage assessment criterion table for determining the battery damage level is constructed as follows.

TABLE 1
Three-Level Damage Assessment Criteria Table

| Damage | | Transportation |
|---|---|---|
| Level | Assessment Criteria | Recommendation |
| Level-One | The wrinkling area ratio of the battery electrode plate is | Transportation |
| | less than 5% and no separator crack is present | permitted |
| Level-Two | The crack length of the separator is greater than 2 mm or | Warning and |
| | the wrinkling area ratio of the battery electrode plate is | reinforced packaging |
| | between 5% and 15% | required |
| Level- | Electrolyte leakage or electrode plate fracture is identified | Transportation |
| Three | | prohibited |

In the damage level assessment process, a sequential evaluation is conducted from Level-Three to Level-One. When the battery meets the standard conditions for a particular damage level, that damage level is assigned as the final assessment result for the battery, and subsequent evaluation steps are terminated.

When the damage level after the battery corner drop test is Level-One, the battery is considered capable of safely completing the transportation type and standard environment corresponding to the drop height. When the damage level after the battery corner drop test is Level-Two, the battery is considered to have transportation risks under the transportation type and standard environment, and the external packaging of the battery needs to be reinforced to meet safety transportation requirements.

When the damage level after the battery corner drop test is Level-Three, or when the incidence rate of Level-Three damage in a plurality of tests under a combination of height and angle is >20%, the battery is considered not capable of safely completing the corresponding transportation type.

The damage analysis module is further configured to generate a test report for the tester. The test report includes CT image evidence, the damage level, and transportation packaging improvement suggestions. The transportation packaging improvement suggestions are obtained by analyzing data acquired by the drop data acquisition module.

For example, the analysis of the drop trajectory using data collected by the high-speed camera comprises a landing angle distribution analysis, a rebound height attenuation analysis, and a motion trajectory deviation analysis.

The landing angle distribution analysis is performed to count a contact frequency for different corners and identify a high-risk drop posture, wherein reinforced protection is implemented for a corner having an acute angle landing probability exceeding 30%.

The rebound height attenuation analysis is performed to calculate a height difference of the battery before and after dropping and evaluate an energy absorption efficiency of a packaging material, wherein the packaging material is ideal if a rebound height is maintained within 10% of an original height.

The motion trajectory deviation analysis is performed to analyze an offset trajectory of a center of gravity of the battery during dropping and optimize an internal fixing device, wherein optimization comprises adding an anti-slip pad or a snap-fit structure.

The analysis of impact characteristics using data collected by the three-axis accelerometer comprises a peak acceleration threshold analysis, an impact pulse width analysis, and a spectral energy distribution analysis.

The peak acceleration threshold analysis is performed to establish an acceleration limit that the battery can withstand, wherein an impact level of ≥50 g is determined to cause internal structural failure, and packaging cushioning design requirements are derived accordingly.

The impact pulse width analysis is performed to analyze a duration of acceleration waveforms and select a cushioning material with a corresponding response speed, wherein a foam material is suitable for a long pulse and a honeycomb structure is suitable for a short pulse.

The spectral energy distribution analysis is performed to identify main frequency bands through a Fast Fourier Transform (FFT) and design a band-pass damping structure, wherein resonance peaks are suppressed using a viscoelastic material.

The analysis of structural strength using data collected by strain gauges comprises a stress concentration factor analysis, a stress wave propagation path analysis, and a cumulative fatigue damage analysis.

The stress concentration factor analysis is performed by generating a stress nephogram of a battery shell and performing topological optimization for an area where a safety factor is less than 1.5 and stress exceeds a material yield strength.

The stress wave propagation path analysis is performed by tracking a stress wave transmission trajectory and adding a stress-relief groove at a key node, the key node comprising a weld seam or a flange edge.

The cumulative fatigue damage analysis is performed to evaluate a repeated drop life using Miner's rule and optimize a standard for a number of packaging cycles.

The analysis of a deformation mode using data collected by the laser range finder comprises a permanent deformation amount control analysis, a dynamic stiffness matching analysis, and a modal shape optimization analysis.

The permanent deformation amount control analysis is performed by setting a shell deformation threshold, wherein a maximum allowable deformation rate for length, width, and height is 0.5%, and wherein a reinforcement rib is implemented or a high-strength steel is adopted if the threshold is exceeded.

The dynamic stiffness matching analysis is performed by analyzing a nonlinear stiffness variation of the shell during dropping and designing a variable stiffness buffer layer comprising a gradient foam structure.

The modal shape optimization analysis is performed by comparing a design mode with a measured vibration mode and adjusting a position of a packaging support point to avoid a resonance amplification effect.

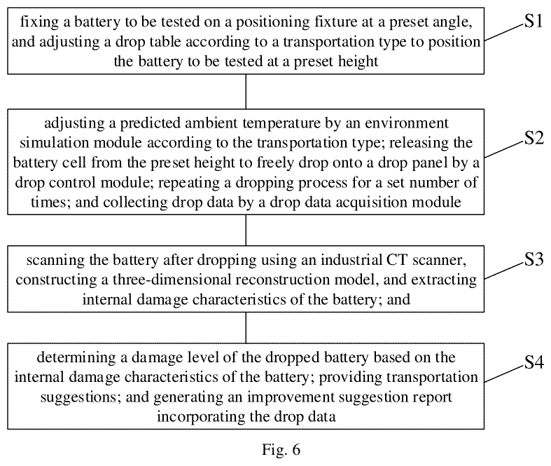

As shown in FIG. 6, a corner drop test method for a power lithium battery cell in a transportation environment includes the following steps: S1, S2, S3, and S4.

S1, fixing a battery to be tested on a positioning fixture at a preset angle, and adjusting a drop table according to a transportation type to position the battery to be tested at a preset height.

S2, adjusting a predicted ambient temperature by an environment simulation module according to the transportation type; releasing the battery cell from the preset height to freely drop onto a drop panel by a drop control module; repeating a dropping process for a set number of times; and collecting drop data by a drop data acquisition module.

S3, scanning the battery after dropping using an industrial CT scanner, constructing a three-dimensional reconstruction model, and extracting damage characteristics.

S4, determining a damage level of the dropped battery based on the damage characteristics; providing transportation suggestions; and generating an improvement suggestion report incorporating the drop data.

In S1, fixing the battery to be tested on the positioning fixture at a preset angle specifically comprises: placing the battery to be tested on the support plate assembly of the positioning fixture, ensuring that the corner to be dropped of the battery is aligned with the circular hole on the contact line between the first support plate and the second support plate; fixing a non-adjacent diagonal corner of the dropping corner of the battery by the electromagnetic chuck; and adjusting a spatial position of the electromagnetic chuck to enable firm adsorption of the battery.

In S2, releasing the battery cell from the preset height to freely drop onto a drop panel by a drop control module specifically comprises: at the moment when the first support plate and the second support plate move away from each other to open, an electrical connection of a coil of the electromagnetic chuck is disconnected; both upper and lower ends of the battery lose support or attraction; and the battery falls from the height of the first support plate and the second support plate in a free state to impact and contact the drop panel.

In S4, determining the damage level of the dropped battery based on the damage characteristics specifically comprises: determining the damage level of the battery according to the three-level damage assessment criteria table. When the wrinkling area ratio of the electrode plate is less than 5% and no separator crack is present, the damage is determined as Level-One damage and transportation is permitted. If the crack length of the separator is greater than 2 mm, or the wrinkling area ratio of the electrode plate is between 5% and 15%, the damage is determined as Level-Two damage, and a warning and reinforced packaging are required. When electrolyte leakage or electrode plate fracture occurs, the damage is determined as Level-Three damage and transportation is prohibited. If a level-three damage rate in a plurality of tests under a combination of a certain height and angle is greater than or equal to 20%, the battery is considered not capable of safely completing the corresponding transportation type.

The above descriptions are merely embodiments of the present disclosure, and well-known specific technical solutions and/or characteristics in the field are not described in excessive detail herein. It should be pointed out that those skilled in the art may make several modifications and improvements without departing from the spirit and scope of the technical solutions of the present disclosure, and these modifications and improvements should also be regarded as the protection scope of the present disclosure. These modifications and improvements will not affect the implementing effects of the present disclosure and the practicality of the patent. The protection scope claimed in the present disclosure shall be subject to the content of the claims, and the specific embodiments and other descriptions in the specification may be used to interpret the content of the claims.

What is claimed is:

1. A corner drop test system for a power lithium battery cell in a transportation environment, comprising:
a parameter control module, configured to set a drop height for a battery corner drop test according to a pre-established correspondence between a transportation type, a drop scenario, and the drop height;
a drop control module, configured to perform the battery corner drop test according to the set drop height and a drop angle; wherein the drop control module comprises a drop table and a positioning fixture; and the drop table is configured to adjust the drop height for the battery corner drop test, and the positioning fixture is configured to adjust the drop angle for the battery corner drop test;
an environment simulation module, comprising a temperature control chamber, wherein the temperature control chamber is configured to simulate high and low temperature environments during transportation according to the transportation type; and the drop table and the positioning fixture are located in the temperature control chamber; and
a damage analysis module, configured to scan a battery image after dropping, generate a three-dimensional reconstructed image of an internal structure of the battery based on the battery image, quantify internal damage characteristics of the battery through the three-dimensional reconstructed image, determine a battery damage level based on the internal damage characteristics of the battery, and determine a transportation risk under the corresponding transportation type and transportation packaging improvement suggestions based on the battery damage level.

2. The corner drop test system for the power lithium battery cell in the transportation environment according to claim 1, wherein:
the transportation type comprises road transportation, rail transportation, water transportation, and air transportation;
the drop scenarios for road transportation comprise manual handling drops and forklift and rack operation drops;
the drop scenarios for rail transportation comprise forklift and rack operation drops;
the drop scenarios for water transportation comprise container transfer drops;
the drop scenarios for air transportation comprise aircraft cargo hold drops; and
the drop height range for manual handling drops is 0.8 m to 1.2 m, the drop height range for forklift and rack operation drops is 1.5 m to 3.5 m; the drop height for container transfer drops is 6 m; and the drop height for aircraft cargo hold drops is 5.4 m.

3. The corner drop test system for the power lithium battery cell in the transportation environment according to claim 2, wherein the parameter control module is further configured to set the drop angle for the battery corner drop test.

4. The corner drop test system for the power lithium battery cell in the transportation environment according to claim 3, wherein the internal damage characteristics of the battery comprise: a wrinkling area ratio of a battery electrode plate, a crack length of a battery separator, and a displacement of a battery tab;
the wrinkling area ratio of the battery electrode plate is calculated using an image segmentation algorithm by: segmenting a battery electrode plate region in the three-dimensional reconstructed image using the image segmentation algorithm to separate a contour of the battery electrode plate and determine an area of the battery electrode plate; identifying wrinkled portions on a surface of the battery electrode plate caused by drop impact; extracting all wrinkled regions on the battery electrode plate and calculating a total area of the wrinkled regions; and obtaining the wrinkling area ratio of the battery electrode plate by comparing the total area of the wrinkled regions with the area of the battery electrode plate;
the crack length of the battery separator is calculated using an edge detection algorithm by: identifying a separator region image in the three-dimensional reconstructed image; identifying edge portions where grayscale values undergo an abrupt change in the separator region image using the edge detection algorithm; capturing a starting point, an extension path, and an endpoint of a crack based on the edge portions; and calculating to obtain the crack length of the battery separator; and
the displacement of the battery tab is calculated using a point cloud registration technique by: acquiring three-dimensional point cloud data of the battery tab after dropping; simultaneously retrieving original three-dimensional point cloud data of the battery tab before dropping; aligning and matching the two sets of point cloud data using the point cloud registration technique; finding a spatial position correspondence of each preset feature point on the battery tab before and after dropping; calculating a displacement vector of each preset feature point; and integrating to obtain the displacement of the battery tab; wherein if the displacement of the battery tab is greater than a preset tab displacement threshold, electrode plate fracture is determined.

5. The corner drop test system for the power lithium battery cell in the transportation environment according to claim 4, wherein when the damage analysis module determines the battery damage level based on the internal damage characteristics of the battery and determines the transportation risk under the corresponding transportation type and the transportation packaging improvement suggestions based on the battery damage level:
if the wrinkling area ratio of the battery electrode plate is less than 5% and no separator crack is present, the battery is determined to have Level-One damage, and transportation is permitted;
if the crack length of the separator is greater than 2 mm, or the wrinkling area ratio of the battery electrode plate is between 5% and 15%, the battery is determined to have Level-Two damage, and a warning and reinforced packaging are required;
if electrolyte leakage or electrode plate fracture is identified, the battery is determined to have Level-Three damage, and transportation is prohibited; and
if a level-three damage rate in a plurality of tests under a combination of a certain height and angle for a test battery is greater than or equal to 20%, the battery is considered not capable of safely completing the corresponding transportation type.

6. The corner drop test system for the power lithium battery cell in the transportation environment according to claim 5, wherein the corner drop test system further comprises a drop data acquisition module, the drop data acquisition module comprises a high-speed camera configured to capture an instant when the battery contacts upon dropping, a three-axis accelerometer configured to collect acceleration changes of the battery at the moment of dropping, strain gauges configured to collect corner stress changes of the battery during dropping, and a laser range finder configured to detect a shell deformation rate of the battery after dropping; and
the damage analysis module is further configured to generate a test report for a tester, the test report comprises Computed Tomography (CT) image evidence, the battery damage level, and the transportation packaging improvement suggestions; the transportation packaging improvement suggestions are obtained by analyzing data acquired by the drop data acquisition module.

7. The corner drop test system for the power lithium battery cell in the transportation environment according to claim 6, wherein the drop table comprises a drop panel configured to impact and contact with the dropping battery, the drop panel is provided with a lifting mechanism configured to control a height of the positioning fixture, the positioning fixture comprises a connection base, a support plate assembly, and an electromagnetic chuck; the support plate assembly and an electromagnetic chuck assembly are mounted on the connection base, and the connection base is in transmission connection with the lifting mechanism;
the lifting mechanism is a screw lifting mechanism, a screw is vertically arranged, and a driving end of the screw is directly connected to a servo motor via a coupling, a nut is threadedly engaged with the screw of the lifting mechanism, and the connection base is fixedly connected to the nut, converting a rotational motion of the screw into a vertical movement of the connection base, thereby controlling the battery drop height;
the support plate assembly is configured to provide a placement plane for a battery to be tested, and comprises a first support plate and a second support plate arranged in parallel; the first support plate and the second support plate are arranged opposite to each other and are in transmission connection with a transmission mechanism; and the transmission mechanism drives the first support plate and the second support plate to move toward each other to close or move away from each other to open; and
when the first support plate and the second support plate move toward each other to close, a circular hole is provided on a contact line between the first support plate and the second support plate, and the circular hole is configured to receive a corner to be dropped of the battery to be tested; the electromagnetic chuck is located above the circular hole and is configured to fix a non-adjacent diagonal corner of the dropping corner of the battery; a coil in the electromagnetic chuck is connected to a power supply; and operation or deactivation of the electromagnetic chuck is controlled by controlling connection or disconnection of the coil and the power supply.

8. The corner drop test system for the power lithium battery cell in the transportation environment according to claim 7, wherein the high-speed camera captures the battery dropping process from a plurality of angles, the high-speed camera located directly in front of the drop table is configured to capture the instant when the battery contacts upon dropping; the three-axis accelerometer is fixed at a center of gravity position of the battery; and at least four strain gauges are uniformly distributed and fixed near the dropping corner of the battery.

9. A method for implementing the corner drop test system for the power lithium battery cell in the transportation environment according to claim 1, comprising the following steps:
S1, fixing a battery to be tested on a positioning fixture at a preset angle, and adjusting a drop table according to a transportation type to position the battery to be tested at a preset height;
S2, adjusting a predicted ambient temperature by an environment simulation module according to the transportation type; releasing the battery cell from the preset height to freely drop onto a drop panel by a drop control module; repeating a dropping process for a set number of times; and collecting drop data by a drop data acquisition module;
S3, scanning the battery after dropping using an industrial CT scanner, constructing a three-dimensional reconstruction model, and extracting internal damage characteristics of the battery; and
S4, determining a damage level of the dropped battery based on the internal damage characteristics of the battery; providing transportation suggestions; and generating an improvement suggestion report incorporating the drop data.

10. The method according to claim 9, wherein in step S2, analyzing a drop trajectory using data collected by a high-speed camera in the drop data acquisition module comprises: performing landing angle distribution analysis to identify high-risk drop postures; performing rebound height attenuation analysis to evaluate energy absorption efficiency of packaging materials; and performing motion trajectory deviation analysis to optimize internal fixing devices;
analyzing impact characteristics using data collected by a three-axis accelerometer comprises: performing peak acceleration threshold analysis to establish an acceleration limit that the battery is capable of withstanding; performing impact pulse width analysis to select a cushioning material with a corresponding response speed; and performing spectral energy distribution analysis to design a band-pass damping structure;
analyzing structural strength using data collected by strain gauges comprises: performing stress concentration factor analysis to generate a stress cloud diagram of the battery shell; performing stress wave propagation path analysis to add stress-relief grooves at key nodes; and performing cumulative fatigue damage analysis to optimize a standard for the number of packaging cycles; and
analyzing a deformation mode using data collected by a laser rangefinder comprises: performing permanent deformation amount control analysis to set a shell deformation threshold; performing dynamic stiffness matching analysis to design a variable stiffness buffer layer; and performing modal shape optimization analysis to adjust positions of packaging support points to avoid resonance amplification effects.
